(19) United States
(12) Patent Application Publication
(10) Pub. No.: US 2024/0270593 A1
(43) Pub. Date: Aug. 15, 2024

(54) METHOD OF SYNTHESIZING ZINC OXIDE NANOROSES

(71) Applicant: KING FAISAL UNIVERSITY, AL-AHSA (SA)

(72) Inventors: FAHEEM AHMED, Al-Ahsa (SA); NISHAT ARSHI, Al-Ahsa (SA); SHALENDRA KUMAR, Al-Ahsa (SA); NAGIH MOHAMMED SHAALAN, Al-Ahsa (SA); GHAZZAI ALMUTAIRI, Al-Ahsa (SA); BANDAR ALOTAIBI, Al-Ahsa (SA); THAMRAA ALSHAHRANI, Al-Ahsa (SA); P.M.Z. HASAN, Al-Ahsa (SA)

(21) Appl. No.: 18/167,832

(22) Filed: Feb. 10, 2023

(51) Int. Cl. C01G 9/02; C23C 14/02; C23C 14/16; C23C 14/30

(52) U.S. Cl. CPC C01G 9/02; C23C 14/021; C23C 14/16; C23C 14/30; C01P 2004/30; C01P 2004/64

(57) ABSTRACT

The method for synthesizing zinc oxide nanoroses is a green, fast, and cost-effective approach for the growth of ZnO nanoroses in which a sheet of vertically aligned and interconnected sheet of ZnO nanospheres are grown on a titanium buffer layer coated on a silicon substrate, the nanospheres mimicking a rose-like structure. According to the method, a film of titanium is first deposited on a Si/SiO₂ substrate by an e-beam evaporation method. Then, the titanium film coated substrate is suspended upside down in a solution of zinc nitrate (0.011 M-0.055M) in an aqueous solution of hexamethylenetetramine (0.011 M-0.055M) and heated to 50-100° C. with vigorous stirring for 60-180 min. The resulting ZnO nanoroses are washed with de-ionized water and air-dried for 12-24 hours. The ZnO nanoroses are suitable for use for various device applications in electronics and in biomedical systems.

### BACKGROUND

### 1. Field

The disclosure of the present patent application relates to nanostructures, and particularly to a method for synthesizing zinc oxide nanoroses.

### 2. Description of the Related Art

In recent decades, research into the properties of nanoparticles has led to significant advances in many fields of technology. The properties of nanoparticles may be greatly affected, not only by the size of the particles, but also by the elemental composition, the nature of any substrate to which they are attached, the morphology or structural shape of the nanoparticles, and many other factors.

In dentistry, for example, nanoparticles have been found useful for improving dental implant procedures, including acting as a carrier for drugs, for increasing bonding to bone, for helping to prevent the subsequent development of dental caries, etc. The nanoparticles used in this field have included, e.g., gold, silver, zinc oxide, titanium, silicon, and others. Zinc oxide, for example, is known to exhibit antibacterial properties. It has also been found that the strength of antibacterial protection provided by zinc oxide nanoparticles is affected by the morphology or structural shape of the nanoparticles. Hence, there has been a significant amount of research in recent years to develop stable zinc oxide nanoparticles in a variety of shapes. Thus, a method for synthesizing zinc oxide nanoroses solving the aforementioned problems is desired.

### SUMMARY

The method for synthesizing zinc oxide nanoroses is a green, fast, and cost-effective approach for the growth of ZnO nanoroses in which a sheet of vertically aligned and interconnected sheet of ZnO nanospheres are grown on a titanium buffer layer coated on a silicon substrate, the nanospheres mimicking a rose-like structure. According to the method, a film of titanium is first deposited on a Si/SiO₂ substrate by an e-beam evaporation method. Then, the titanium film coated substrate is suspended upside down in a solution of zinc nitrate (0.011 M-0.055M) in an aqueous solution of hexamethylenetetramine (0.011 M-0.055M) and heated to 50-100° C. with vigorous stirring for 60-180 min. The resulting ZnO nanoroses are washed with de-ionized water and air-dried for 12-24 hours. The ZnO nanoroses are suitable for use for various device applications in electronics and biomedical systems.

These and other features of the present subject matter will become readily apparent upon further review of the following specification.

### BRIEF DESCRIPTION OF THE DRAWINGS

FIG. 1 is a SEM micrograph of exemplary zinc oxide nanoroses at 20× magnification.

FIG. 2 is a SEM micrograph of exemplary zinc oxide nanoroses at 50× magnification.

FIG. 3 is a SEM micrograph of exemplary zinc oxide nanoroses at 100× magnification.

Similar reference characters denote corresponding features consistently throughout the attached drawings.

### DETAILED DESCRIPTION OF THE PREFERRED EMBODIMENTS

The method for synthesizing zinc oxide nanoroses is a green, fast, and cost-effective approach for the growth of ZnO nanoroses in which a sheet of vertically aligned and interconnected sheet of ZnO nanospheres are grown on a titanium buffer layer coated on a silicon substrate, the nanospheres mimicking a rose-like structure. According to the method, a film of titanium is first deposited on a Si/SiO₂ substrate by an e-beam evaporation method. Then, the titanium film coated substrate is suspended upside down in a solution of zinc nitrate (0.011 M-0.055M) in an aqueous solution of hexamethylenetetramine (0.011 M-0.055M) and heated to 50-100° C. with vigorous stirring for 60-180 min. The resulting ZnO nanoroses are washed with de-ionized water and air-dried for 12-24 hours. The ZnO nanoroses are suitable for use for various device applications in electronics and in biomedical (dental and orthopedic implants) systems.

The method for synthesizing zinc oxide nanoroses will be better understood with reference to the following examples.

### Example 1

Coating Silicon Substrate with Titanium Film Buffer Layer

Titanium (Ti) films were deposited by electron-beam evaporation technique onto Si/SiO₂ (100) substrate by evaporating Ti metal. The films were deposited on Si/SiO₂ (100) substrates (area=40×20 mm²), which were oxidized in a furnace for 1-2 hours at 1000° C.-1200° C. and cleaned by rinsing in ultrasonic baths of acetone and methanol prior to the deposition, and then fixed in a single-rotation holder mounted 300 mm above the vapor source. Commercial Ti metal (99.9999%; 3.2 mm diameter×3.2 mm length, purchased from Alfa Aesar) slugs were placed into a crucible as evaporation sources for film deposition. The vacuum chamber was equipped with a turbo-molecular pump, which is horizontally fixed to the chamber, backed by a rotary pump and could produce an ultimate vacuum of 2.1×10⁻⁶-7.2×10⁻⁷ Torr. A series of Ti films with substrates at room-temperature, 100° C., 200° C., and 300° C. were deposited for 5-60 min at a power of 500-3000 Watt.

### Example 2

### Synthesizing Zinc Oxide Nanoroses

The substrate of deposited Ti film on Si/SiO₂ substrate was used for the growth of ZnO nanoroses. In this step, the substrate was put upside down in a solution. In this solution, Zinc nitrate (0.011 M-0.055 M) was added to an aqueous solution of hexamethylenetetramine (0.011 M-0.055M) and heated to 50-100° C. with vigorous stirring. Then, the growth of the ZnO was continuous at 50-100° C. for 60-180 min. Finally, as-prepared ZnO nanoroses were thoroughly washed with deionized water, and dried in air at 80-90° C. for 12-24 h before characterization.

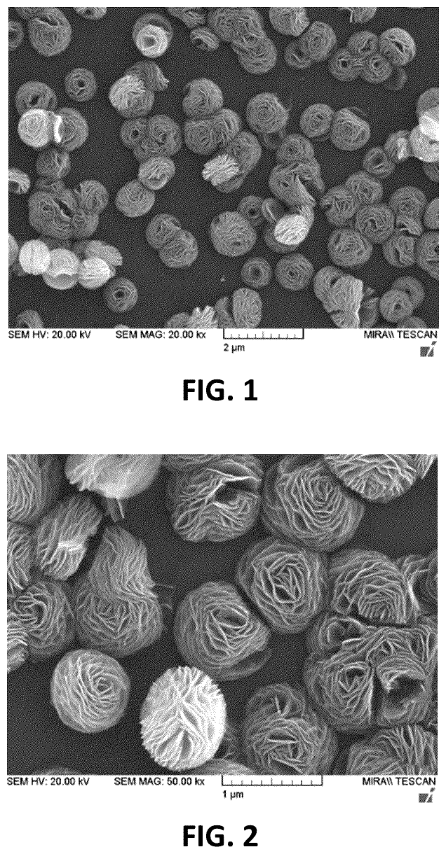

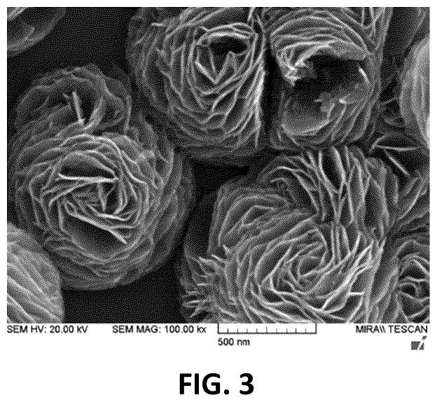

FIG. 1 is a SEM micrograph of exemplary zinc oxide nanoroses prepared by the above procedure at 20× magnification. FIG. 2 is a SEM micrograph of exemplary zinc oxide nanoroses prepared by the above procedure at 50× magnification. FIG. 3 is a SEM micrograph of exemplary zinc oxide nanoroses prepared by the above procedure at 100× magnification.

In this method, the morphology can be defined as “hierarchical arrangement of nanosheets producing rose-like structures. These nanosheets are arranged hierarchically to form nanorose superstructures with different morphologies than nanospheres. Additionally, the hierarchical ZnO nanoroses originate from the self-assembly of the single-crystalline nanosheets with preferred orientation along the c-axis. In nanospheres, the particles are arrange randomly in a manner so that they can produce solid sphere-like morphology. The nanoroses have a mimic structure of natural roses, thus, are named nanorose.

The structural and morphological properties of the as-grown ZnO nanospheres were confirmed by various analyses. Structural studies confirmed the formation of highly crystalline ZnO with c-axis orientation. Morphological studies showed that the grown ZnO on Ti buffered layered Si substrate are nanospheres in which nanosats are interconnected and vertically aligned, mimicking a rose-like structure. The size of the synthesized nanoroses was measured by FESEM technique. The lateral dimension of the nanoroses ranged from 0.5 microns to 1 micron, and the thickness of the nanosheets ranged from 10 to 20 nm, respectively. These ZnO nanospheres could be useful for biomedical device applications, including dental and orthopedic implants. The presented approach can be applied to the large-scale production of other metal oxide nanostructures.

It is to be understood that the method for synthesizing zinc oxide nanoroses is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A method for synthesizing zinc oxide nanoroses, comprising the steps of:
coating a buffer layer of titanium film on a silicon substrate using e-beam evaporation, the e-beam evaporation comprising the steps of oxidizing the substrate of silicon/silicon dioxide in a furnace for between 1 and 2 hours at a temperature between 1000° C. and 1200° C. to provide an oxidized substrate, cleansing the oxidized substrate in ultrasonic baths of acetone and methanol, securing the cleansed substrate in a single-rotation holder above a crucible in a vacuum chamber, reducing pressure in the vacuum chamber to between 2.1×10⁻⁶ and 7.2×10⁻⁷ Torr;
heating titanium slugs in the crucible to produce titanium vapor rising above the crucible to form the titanium film on the cleansed substrate; and
suspending the coated substrate upside down in an aqueous solution of zinc nitrate containing hexamethylenetetramine to form the zinc oxide nanoroses extending vertically from the coated substrate, wherein the zinc oxide nanoroses have a lateral dimension ranging from about 0.5 microns to about 1 micron and a thickness ranging from about 10 nm to about 20 nm.

2. The method for synthesizing zinc oxide nanoroses according to claim 1, wherein the step of suspending the coated substrate further comprises a step of heating the aqueous solution to 50-100° C. and wherein the aqueous solution consists of zinc nitrate and hexamethylenetetramine.

3. The method for synthesizing zinc oxide nanoroses according to claim 2, wherein the step of heating the aqueous solution comprises heating the aqueous solution for between 60 minutes and 180 minutes with stirring.

4. The method for synthesizing zinc oxide nanoroses according to claim 1, further comprising a step of washing the formed zinc oxide nanoroses with de-ionized water.

5. The method for synthesizing zinc oxide nanoroses according to claim 4, further comprising a step of air-drying the formed zinc oxide nanoroses for between 12 hours and 24 hours.

6. The method for synthesizing zinc oxide nanoroses according to claim 1, wherein the aqueous solution of zinc nitrate and hexamethylenetetramine has an equal concentration of between 0.011M and 0.055M.

7. The method for synthesizing zinc oxide nanoroses according to claim 1, wherein said step of coating the buffer layer comprises coating the buffer layer of titanium film on the silicon substrate by e-beam evaporation.

8.-10. (canceled)
